(19) United States
(12) Patent Application Publication
(10) Pub. No.: US 2026/0277442 A1
(43) Pub. Date: Sep. 17, 2026

(54) READ REFERENCE VOLTAGE MANAGEMENT IN FLASH MEMORY

(71) Applicant: Silicon Motion, Inc., Hsinchu County (TW)

(72) Inventors: Yu-Han Hsiao, changhua County (TW); Po-Sheng Chou, Hsinchu County (TW); Yun-Feng Ceng, Miaoli County (TW)

(73) Assignee: Silicon Motion, Inc., Hsinchu County (TW)

(21) Appl. No.: 19/078,235

(22) Filed: Mar. 12, 2025

(51) Int. Cl. G06F 3/06; G11C 16/04; G11C 16/26

(52) U.S. Cl. CPC G06F 3/0613; G06F 3/0659; G06F 3/0679; G11C 16/26; G11C 16/0483

(57) ABSTRACT

A method for performing read reference voltage management on a flash memory includes: managing a first self-learning table based on one or more read retry operations performed using hard-decision decoding; managing a second self-learning table based on one or more read retry operations performed using soft-decision decoding; managing a sticky table based on a read reference voltage level or a read reference voltage level set used in a most recent successful read retry operation, wherein the read reference voltage level or the read reference voltage level set is derived from at least one of the first self-learning table, the second self-learning table, and a read retry operation using soft-decision decoding; and performing a normal read operation based on the sticky table.

### BACKGROUND OF THE INVENTION

### 1. Field of the Invention

The present invention relates to flash memory, and more particularly to a method for performing read reference voltage management in flash memory, related memory controller and data storage device thereof.

### 2. Description of the Prior Art

NAND flash memory cells store data by trapping charges in the floating gate to program different threshold voltage states. However, these stored charges are subject to gradual leakage over time, a phenomenon known as data retention loss. This charge leakage can be accelerated by various factors including high operating temperatures, repeated program/erase (P/E) cycling, and extended data retention periods. As charge leakage occurs, the threshold voltage distributions of memory cells shift from their originally programmed states, potentially leading to read errors when predetermined read reference voltages no longer effectively discriminate between adjacent voltage states.

When read errors occur due to data retention loss, the memory controller initiates error correction mechanisms, typically using error correction code (ECC), to recover the correct data. If the number of errors exceeds the correction capability of the ECC, the memory controller then performs read retry operations, which involve adjusting the read reference voltage and reattempting the read operation in an effort to find a read reference voltage configuration that can successfully retrieve the stored data. However, read retry operations introduce significant performance overhead, as they require multiple read attempts using different voltage levels and extensive ECC computations, leading to increased read latency and potential degradation of endurance due to excessive sensing operations.

Given these challenges, there is a demand in the field for an innovative read reference voltage management method that optimizes read retry operations, reduces unnecessary retries, and enhances the overall efficiency and reliability of NAND flash memory devices.

### SUMMARY OF THE INVENTION

To address the aforementioned challenges, the present invention introduces an adaptive multi-table read reference voltage management architecture that significantly enhances the efficiency of read retry operations in NAND flash memory. In an exemplary embodiment, a flash memory controller implements a hierarchical table structure comprising a first self-learning table, a second self-learning table, and a sticky table to dynamically optimize read reference voltages. The first self-learning table maintains an ordered record of read reference voltages or read reference voltage level sets that have successfully retrieve the stored data through read retry operations using hard-decision decoding. The second self-learning table maintains an ordered record of read reference voltages or read reference voltage level sets that have successfully retrieve the stored data through read retry operations using soft-decision decoding. The sticky table maintains the read reference voltage or the read reference voltage level set used in a most recent successful read retry operation. By leveraging these read reference voltage tables in a structured manner, the present invention effectively narrows the search space for optimal read reference voltages, thereby increasing the probability of successful read operations on the first attempt and increasing the success rate of read retry operations. As a result, when data retention loss occurs, the present invention significantly improves read performance by reducing unnecessary retry attempts and minimizing latency.

According to one embodiment, a method for performing read reference voltage management on a flash memory is provided. The method includes: managing a first self-learning table based on one or more read retry operations performed using hard-decision decoding; managing a second self-learning table based on one or more read retry operations performed using soft-decision decoding; managing a sticky table based on a read reference voltage level or a read reference voltage level set used in a most recent successful read retry operation, wherein the read reference voltage level or the read reference voltage level set is derived from at least one of the first self-learning table, the second self-learning table, and a read retry operation using soft-decision decoding; and performing a normal read operation based on the sticky table.

According to one embodiment, a memory controller for use in a flash memory is provided. The memory controller comprises: a storage unit and a processing unit. The storage unit is configured to store program codes. The processing unit is configured to execute the program code to perform operations on the flash memory, comprising: managing a first self-learning table based on one or more read retry operations performed using hard-decision decoding; managing a second self-learning table based on one or more read retry operations performed using soft-decision decoding; managing a sticky table based on a read reference voltage level or a read reference voltage level set used in a most recent successful read retry operation, wherein the read reference voltage level or the read reference voltage level set is derived from at least one of the first self-learning table, the second self-learning table, and a read retry operation using soft-decision decoding; and performing a normal read operation based on the sticky table.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of an electronic device and a data storage device according to one embodiment of the present invention.

FIG. 2 illustrates various read reference voltage tables for use in a read operation or a read retry operation according to one embodiment of the present invention.

FIGS. 3A-3C illustrate a read flow according to one embodiment of the present invention.

FIG. 4 illustrates a flow chart of a method for performing read reference voltage management on a flash memory according to one embodiment of the present invention.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

Reference throughout this specification to “one embodiment” or “an embodiment” means that a particular feature, structure or characteristic described in connection with the embodiment or example is included in at least one embodiment of the present embodiments. Thus, appearances of the phrases “in one embodiment” or “in an embodiment” in various places throughout this specification are not necessarily all referring to the same embodiment. Furthermore, the particular features, structures or characteristics may be combined in any suitable combinations and/or sub-combinations in one or more embodiments.

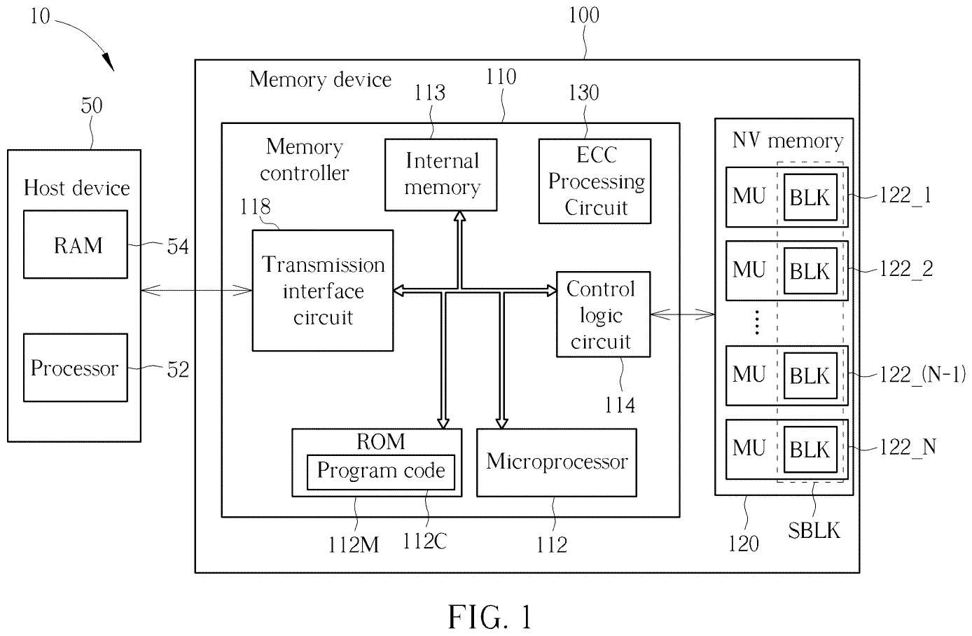

FIG. 1 is a schematic diagram illustrating an electronic device and a data storage device according to one embodiment of the present invention. As illustrated an electronic device 10 comprises a host device 50 and a data storage device 100. The host device 50 may comprise: at least one processor 52 configured to control operations of the host device 50, and a random access memory 54 configured to store data and information required by the processor 52. Examples of the host device 50 may include, but are not limited to: a smartphone, a tablet computer, a wearable device, a personal computer (such as, a desktop computer or a laptop computer), an imaging device (such as, a digital still camera or a video camera), a game console, a car navigation system, a printer, a scanner, or a server system. Examples of the data storage device 100 may include, but are not limited to: a portable memory device (such as a memory card conforming to SD/MMC, CF, MS, XD, or UFS specifications), a solid-state drive (SSD), and various embedded storage devices (such as an embedded storage device conforming to UFS or EMMC specifications).

According to various embodiments, the data storage device 100 may comprise a memory controller 110 and may further comprise a non-volatile (NV) memory 120. The NV memory 120 may comprise one or more NV memory elements, such as a plurality of NV memory elements (MU) 122_1-122_N. In some embodiments, the NV memory 120 may be a NAND flash memory, and the NV memory elements 122_1-122_N may be a plurality of NAND flash memory chips or a plurality of NAND flash memory dies, respectively, but the present invention is not limited thereto.

In some embodiments, the NV memory 120 may include a plurality of memory blocks BLK, which may be grouped into a plurality of superblocks SBLK. The memory block BLK may refer to a physical block and includes a plurality of memory cells. The superblock SBLK may be a unit of a logical memory region required for the memory controller 110 to manage the NV memory 120, where a composition of a superblock SBLK can span across NV memory dies 122_1-122_N. The memory block BLK may be implemented as a memory cell array in which a plurality of memory cells form a two-dimensional (2D) or three-dimensional (3D) array structure. The plurality of memory cells may be single-level cells programmed with one bit or multi-level cells (e.g., double-level cells, triple-level cells or quadruple-level cells) programmed with two bits or more. Moreover, the memory block BLK may include a plurality of pages, where memory cells connected to a same word line may constitute a page. In addition, the memory block BLK may be a unit of an erase operation, and the page may be a unit of program and read operations.

In some embodiments, each of NV memory dies 122_1-122_N is equipped with control circuitry for executing memory operation commands issued by the memory controller 110. Each of NV memory dies 122_1-122_N may include multiple planes, where each plane may have multiple blocks composed of memory cells, along with associated row and column control circuitry. Through multi-plane operation commands, various memory operations can be applied parallel on different planes to perform multi-plane reading, writing or erasing operations.

The memory controller 110 may comprise a processing unit 112, a read-only memory (ROM) 112M, an internal memory 113, a transmission interface circuit 118, an error checking and correction (ECC) processing circuit 130. At least one portion of these circuits and components may be coupled to one another through a bus. The internal memory 113 can be implemented by one or more RAM devices. For example, the internal memory 113 may comprise a static RAM (SRAM) and/or a dynamic RAM (DRAM). The internal memory 113 could be configured to provide internal storage space for the memory controller 110, for example, temporarily storing information, such as data, addresses, commands, mapping information, and/or variables/parameters. In some embodiments, the memory controller 110 may not include DRAM. Instead, the memory controller 110 may rely on host memory buffer (HMB) technology. With the HMB technology, the memory controller 110 could utilize the RAM 54 (such as DRAM) of the host device 50, as a whole, a part or an extension of the internal memory 113, thereby improving read and write performance of the data storage device 100.

In addition, the ROM 112M in this embodiment is configured to store program code 112C, and the processing unit 112 is configured to execute the program code 112C, thereby controlling access to the NV memory 120. The program code 112C may include one or more program modules, such as boot loader code. When the data storage device 100 obtains power from the host device 50, the processing unit 112 may execute an initialization process of the data storage device 100 by executing the program code 112C. During the initialization process, the microprocessor 112 may load a set of in-system programming (ISP) codes (not shown in FIG. 1) from the NV memory 120. The microprocessor 112 can execute the ISP codes so that the data storage device 100 can be operable to perform various functions. According to one embodiment of the present invention, the set of ISP codes may include, but are not limited to: one or more program modules associated with memory access (e.g., reading, writing, and erasing), such as, a read operation module, a lookup table module, a wear leveling module, a read refresh module, a read reclaim module, and a garbage collection module, an sudden power-off recovery(SPOR) module, which are provided to perform corresponding reading, lookup table querying, wear leveling, read refreshing, read reclaiming, garbage collection, SPOR and other operations.

The memory controller 110 controls reading, writing, and erasing of the NV memory 120 through a control logic circuit 114. In addition, the memory controller 110 could perform writing of data based on host commands from the host device 50 and writing of valid data which is read from the NV memory 120 by a garbage collection and/or a wear-leveling operation concurrently. The transmission interface circuit 118 may conform to a specific communications specification, such as, Universal Serial Bus (USB) specification, Secure Digital (SD) interface, Ultra High Speed-I (UHS-I) interface, Ultra High Speed-II (UHS-II), CompactFlash (CF) interface, Multimedia card (MMC) interface, embedded Multimedia Card (eMMC) specification, Serial Advanced Technology Attachment (SATA), Parallel Advanced Technology Attachment (PATA), Peripheral Component Interconnect Express (PCI-E), and Universal Flash Storage (UFS) specification, and may perform communications with the host device 50 according to the specific communications specification.

Typically, the host device 50 may indirectly access the memory device 100, through transmitting host commands and corresponding logic addresses to the memory controller 110. The memory controller 110 receives the host commands and the logic addresses, and translates the host commands to memory operation commands, and further controls the NV memory 120 with the memory operation commands to perform read, program or erase operations upon memory cells or data pages having physical addresses within the NV memory 120.

In some embodiments, a logical-to-physical (L2P) address mapping table having multiple L2P address mapping entries, can be divided into multiple mapping groups. Each mapping group includes a part of entries of the L2P address mapping table and is utilized for performing logical-to-physical address translation. These L2P mapping groups are permanently stored in blocks of NV memory 120 and are loaded into the internal memory 113 when needed. Similarly, a physical-to-logical (P2L) address mapping table having multiple P2L address mapping entries, can be divided into multiple mapping groups. Each mapping group includes a part of entries of the P2L address mapping table and is utilized for performing physical to logical address translation. These P2L mapping groups are permanently stored in blocks of NV memory 120.

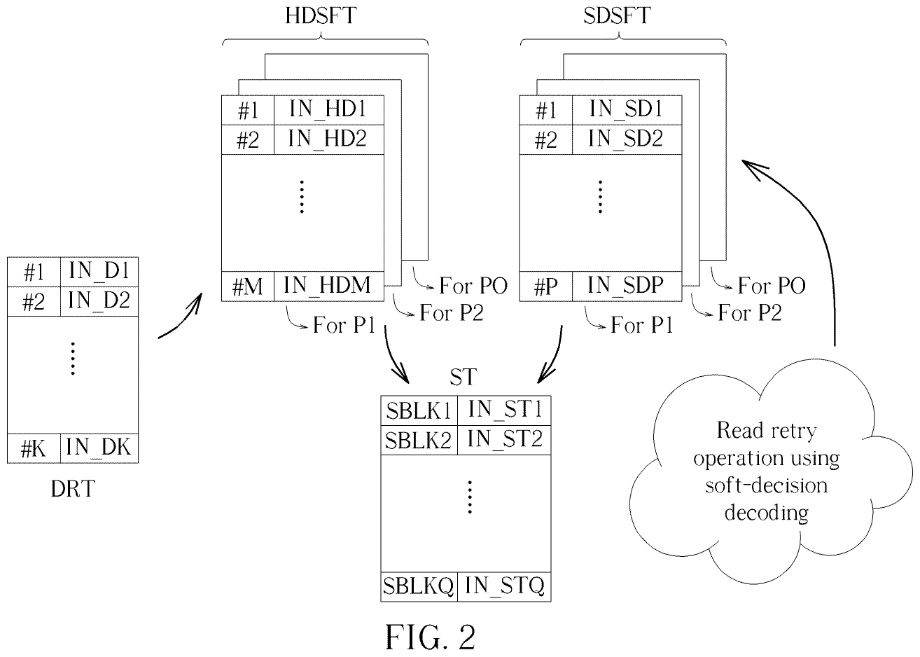

To enhance the efficiency and reliability of read retry operations, the memory controller 110 manages, build and update various read reference voltage management tables, including a sticky table ST, a hard-decision-decoding-based (HD) self-learning table HDSFT (i.e., a first self-learning table) and a soft-decision-decoding-based (SD) self-learning table SDSFT. (i.e., a second self-learning table) Please refer to FIG. 2, which provides a comprehensive view of the read reference voltage management architecture.

Typically, the memory controller 110 records a default read retry table DRT that serves as the foundational reference for read retry operations. The default read retry table DRT may comprise K entries #1- #K, where each entry stores information (e.g. IN_D1-IN_DK) related to a specific read reference voltage level (if the memory cells store one bit per cell (e.g., single-level cells (SLC)), each entry may correspond to an individual read reference voltage level) or a specific read reference voltage level set (if the memory cells store two or more bits per cell (e.g., multi-level cells (MLC), triple-level cells (TLC), or quad-level cells (QLC)), each entry may correspond to a read reference voltage level set comprising multiple read reference voltage levels for different bit levels). According to various embodiments of the present invention, each entry in the default read retry table DRT may store read reference voltage level information in one of the following ways: 1) recording absolute voltage values, where each entry contains explicit read reference voltage levels or read reference voltage level sets for direct application; 2) recording shift information relative to a default read reference voltage level or a default read reference voltage level set, where the entry represents adjustment offset(s) rather than absolute voltage value(s). Please note that the above principles also apply to the sticky table ST, the HD self-learning table HDSFT and the SD self-learning table SDSFT.

Moreover, the memory controller 110 performs read retry operations based on hard-decision decoding and/or soft-decision decoding in response to a failure of a read operation or a read retry operation. During a retry operation base on hard-decision decoding, the memory controller 110 determines a read reference voltage level or a read reference voltage level set based on information of entries in the default read retry table DRT and accordingly performs the read retry operation. If the read retry operation is successful, the determined read reference voltage level or read reference voltage level set is recorded into the HD self-learning table HDSFT for future reference.

As shown in FIG. 2, the HD self-learning table HDSFT is managed per plane of NV memory units 122_1-122_N (e.g., NV memory dies or chips 122_1-122_N), meaning that each plane (e.g., P1, P2, . . . , P0) has a corresponding HD self-learning table HDSFT. For example, an indexed table corresponding to a first plane P1 consists of M entries #1- #M, each storing information (e.g., IN_HD1-IN_HDM) about read reference voltage levels or read reference voltage level sets used in past successful read retry operations with hard-decision decoding. Please note that although in the above embodiments, the management basis of the HD self-learning table HDSFT is a “plane”, this is not a limitation of the present invention. In other embodiments of the present invention, other units may be used as the management basis, such as blocks, super blocks, dies or logical units (LUNs).

When a read retry operation using hard-decision decoding is successful, the read reference voltage level or the read reference voltage level set currently used (selected based on the default read retry table DRT) is stored as a highest-priority entry in a corresponding HD self-learning table HDSFT. The previous highest-priority entry is shifted downward, and all subsequent entries are shifted accordingly. By maintaining the most recently successful read reference voltage levels at the top of the priority, the memory controller 110 can efficiently prioritize highly effective read reference voltage levels in future read retry operations, thereby reducing the number of read retry operations and improving overall read performance.

Moreover, when the read retry operations using hard-decision decoding fail to readout the stored data, the memory controller 110 would perform read retry operations using an iteratively adjusted read reference voltage level or an iteratively adjusted read reference voltage level set based on soft-decision decoding. If a read retry operation using soft-decision decoding is successful, the currently adjusted read reference voltage level or the currently adjusted read reference voltage level set used in a final iteration of soft-decision decoding will be used to update the SD self-learning table SDSFT.

As shown in FIG. 2, the SD self-learning table SDSFT is managed per plane of NV memory units 122_1-122_N e.g., NV memory dies or chips 122_1-122_N), meaning that each plane (e.g., P1, P2, . . . , P0) has a corresponding SD self-learning table SDSFT. For example, the indexed table corresponding to a first plane P1 consists of P entries #1-#P, each storing information about read reference voltage levels or read reference voltage level sets (IN_SD1-IN_SDP) used in past successful read retry operations using soft-decision decoding. When a read retry operation using soft-decision decoding is successful, a currently adjusted read reference voltage level or a currently adjusted read reference voltage level set used in a final iteration used in a final iteration of soft-decision decoding is stored as a highest-priority entry in a corresponding SD self-learning table SDSFT. The previous highest-priority entry is shifted downward, and all subsequent entries are shifted accordingly. Please note that although in the above embodiments, the management basis of the HD self-learning table HDSFT is a “plane”, this is not a limitation of the present invention. In other embodiments of the present invention, other units may be used as the management basis, such as blocks, super blocks, dies or logical units (LUNs).

In addition to the HD self-learning table HDSFT and the SD self-learning table SDSFT, the memory controller 110 also manages the sticky table ST to further optimize the read retry process. The sticky table ST is used to store a read reference voltage level or a read reference voltage level set used in a most recent successful read retry operation, aiming to improve the efficiency of subsequent normal read operations and reduce the need for read retry operations. As shown in FIG. 2, the sticky table ST is indexed by superblocks. Each entry in the sticky table corresponds to a superblock of the NV memory 120, with SBLK1-SBLKQ representing different superblocks. Each entry information IN_ST1-IN_STQ respectively indicates a read reference voltage level or a read reference voltage level set used in a most recent successful read retry operation (using either the hard-decision decoding or the soft-decision decoding) for a corresponding superblock. Please note that although in the above embodiment, the index basis of the sticky table ST is “super block”, this is not a limitation of the present invention. In other embodiments of the present invention, other units may be used as the index basis.

When a read retry operation is successful, the memory controller 110 updates the sticky table ST with the currently used read reference voltage level or the currently used read reference voltage level set. Specifically, the sticky table ST is updated with information derived from one of the following sources: 1) one or more specific entries in the HD self-learning table HDSFT that provided the read reference voltage level or read reference voltage level set used in a successful read retry operation with hard-decision decoding; 2) one or more specific entries in the SD self-learning table SDSFT that provided the read reference voltage level or read reference voltage level set used in a successful read retry operation with soft-decision decoding; and 3) a read reference voltage level or a read reference voltage level set obtained from an iteratively adjusted soft-decision decoding when the read retry operation is successful.

During a normal read operation, the memory controller 110 first checks whether an entry for a target superblock exists in the sticky table ST. If such an entry exists, the read operation is performed using a corresponding read reference voltage level or a corresponding read reference voltage level set determined based on the sticky table ST, instead of a default read reference voltage level or a default read reference voltage level set. This allows the memory controller 110 to avoid unnecessary read retry operations and enhances overall read performance.

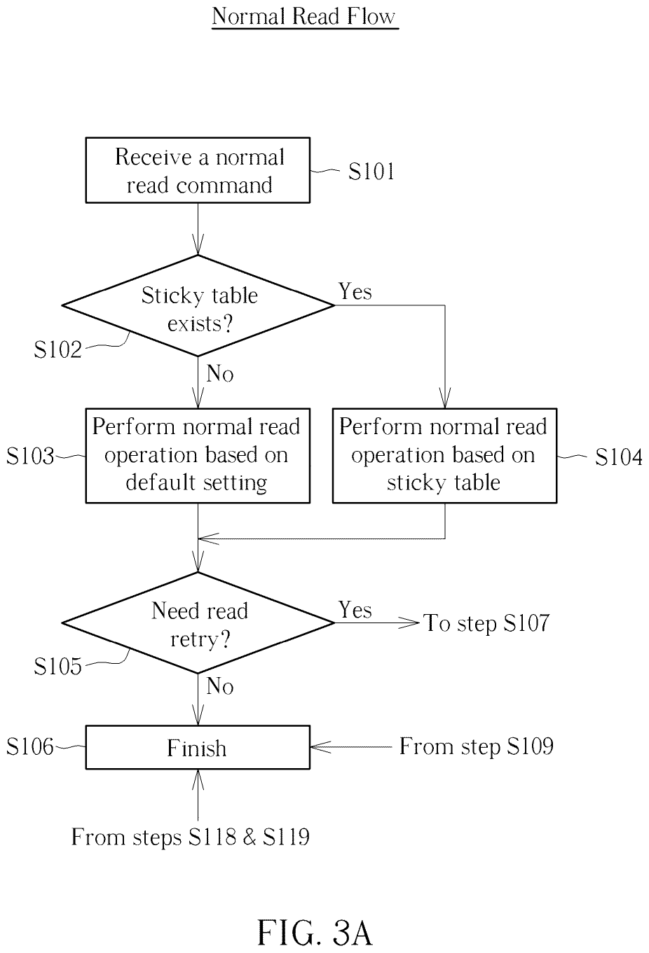

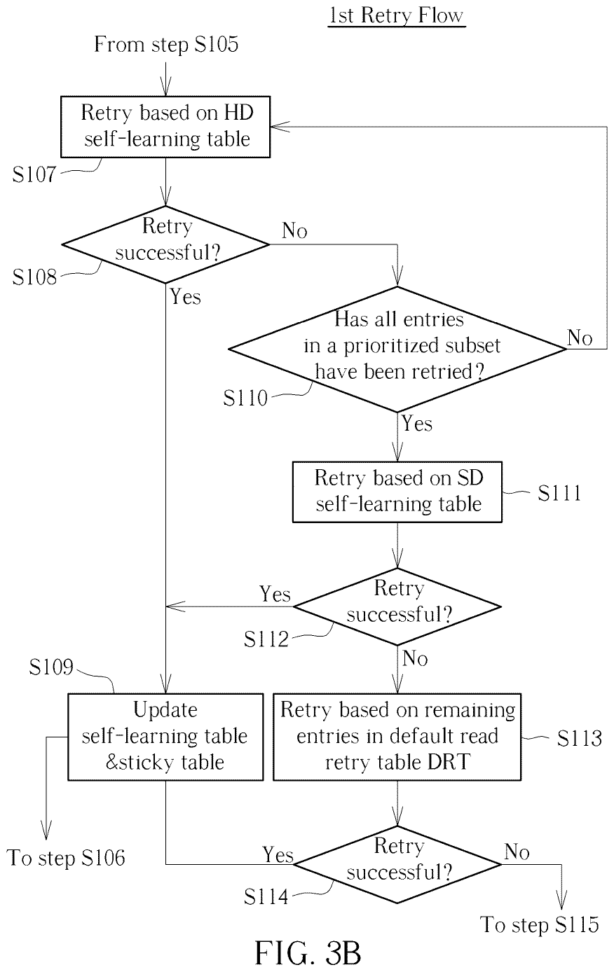

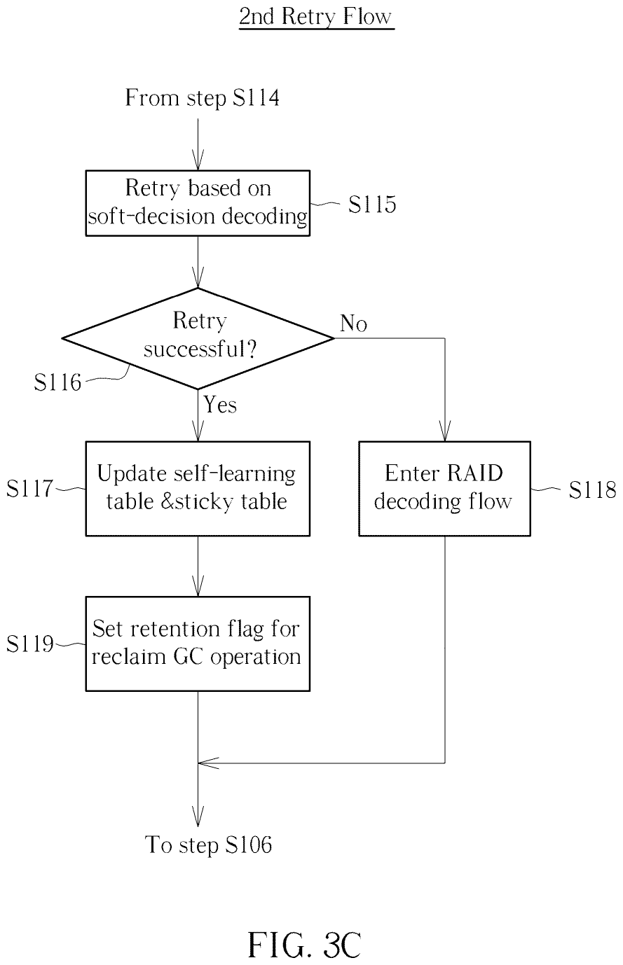

FIGS. 3A-3C collectively illustrate a flow chart of a method for performing read reference voltage management according to one embodiment of the present invention. The method includes a normal read flow, a first retry flow and a second retry flow, and starts from step S101 within the normal read flow. At step S101, the memory controller 110 receives a normal read command from the host device 50. Upon receiving the normal read command, the memory controller 110 determines whether the sticky table ST exists (step S102), where the sticky table ST stores a read reference voltage level or a read reference voltage level set used in a most recent successful read retry operation for a corresponding superblock. In particular, the memory controller 110 extracts a logical address from the normal read command, identifies a corresponding superblock based on the logical address mapping and determines whether the sticky table for the corresponding superblock exits (e.g., whether the sticky table contains a valid entry recording a read reference voltage level or a read reference voltage level set for the corresponding superblock).

If the sticky table ST exists, the memory controller 110 performs the normal read operation using the read reference voltage level or read reference voltage level set determined based on information in the sticky table ST (step S104). If the sticky table ST does not exist, the memory controller 110 performs the normal read operation using a default read reference voltage level or default read reference voltage level (step S103).

After performing the normal read operation, the memory controller 110 determines whether a read retry operation is necessary at step S105. The determination is made by performing an ECC process on data read from the NV memory 120. Specifically, the ECC processing circuit 130 checks whether the read errors are within a correctable range. If the number of read errors is within the correctable range of the ECC, the read operation is considered successful; otherwise, the read operation is determined to have failed, and a read retry operation is required.

In an exemplary embodiment, performing the read operation at step S103 or step S104 includes reading cell voltages of a page or a super page of the NV memory 120, converting the read cell voltages into a codeword (e.g., user data and redundancy information), and performing the ECC process on the codeword. The read operation is considered failed when the ECC process fails to correct the errors. For example, an ECC failure may be due to the fact that the number of bit errors in the codeword exceeds the error correctable range of the ECC.

If a read retry operation is not required, the flow ends at step S106. However, if a read retry operation is required, the flow transitions into the first retry flow, beginning at step S107, wherein the first retry flow includes performing read retry operations using hard-decision decoding.

At step S107, the memory controller 110 attempts a read retry operation using a read reference voltage level or a read reference voltage level set determined based on information of one of a prioritized subset of entries in the HD self-learning table HDSFT. The prioritized subset refers to a predetermined number of high-priority entries (e.g., the first 6 out of 10 recorded entries in the HD self-learning table HDSFT). In addition, as the HD self-learning information is managed by plane, meaning that each plane of the NV memory 120 has a corresponding HD self-learning table HDSFT, when performing the read retry operation, the memory controller 110 selects the HD self-learning table HDSFT corresponding to the plane to which the logic address of the normal read command is mapped.

At step S108, it is determined whether the read retry operation based on hard-decision ECC decoding is successful. The read retry operation is deemed successful if the number of detected errors is within the correctable range of the ECC process; otherwise, the read retry operation is considered unsuccessful. If the determination of step S108 is yes, the flow proceeds to step S109, where the HD self-learning table HDSFT and the sticky table are updated accordingly before the flow concludes at step S106. In particular, updating the HD self-learning table HDSFT involves reordering its entries (i.e., information of the determined read reference voltage level or read reference voltage level set used in the successful read retry operation is stored as the highest-priority entry, and the existing entries are shifted downward accordingly). Furthermore, the sticky table ST is updated with the determined read reference voltage level or read reference voltage level set on a superblock basis.

At step S110, it is determined whether all entries in the prioritized subset of the HD self-learning table HDSFT have been retried. If the prioritized subset has not been exhausted, the flow loops back to step S107, where information of a next highest-priority entry in the prioritized subset is used to determine the read reference voltage level or read reference voltage level set for performing another read retry operation. If read reference voltage levels or read reference voltage level sets determined based on information of all entries in the prioritized subset have been retried and no successful read operation has been achieved, the flow proceeds to step S111, where read retry operations are performed based on information of entries in the SD self-learning table SDSFT.

At step S111, the memory controller 110 attempts a read retry operation using a read reference voltage level or a read reference voltage level set determined based on information of one of the entries in the SD self-learning table SDSFT. The SD self-learning information is also managed by plane, meaning that each plane in the NV memory 120 has a corresponding SD self-learning table SDSFT. The memory controller 110 retrieves information of entries in the SD self-learning table SDSFT corresponding to the plane to which the logic address of the normal read command is mapped and accordingly determine a read reference voltage level or a read reference voltage level set based on information of entries.

At step S112, it is determined whether the read retry operation using the SD self-learning table SDSFT is successful by performing hard-decision ECC decoding. If the read retry operation is successful, the flow proceeds to step S109, where the SD self-learning tables SDSFT and the sticky table ST are updated accordingly, before the flow concludes at step S106. In particular, updating the SD self-learning table SDSFT involves reordering its entries (i.e., information of the determined read reference voltage level or read reference voltage level set used in the successful read retry operation is stored as the highest-priority entry, and the existing entries are shifted downward accordingly). Furthermore, the sticky table ST is updated with the determined read reference voltage level or read reference voltage level set on a superblock basis.

If the determination at step S112 is no, the flow proceeds to step S113, where retry operations are performed based on remaining entries in the default read retry table DRT. Specifically, after exhausting all entries of the prioritized subset of entries in the HD self-learning table HDSFT (e.g., first 6 entries) and all of the entries in the SD self-learning table SDSFT (e.g., all 10 entries) without a successful read retry operation, the flow transitions to step S113. At this step, the memory controller 110 attempts a read retry operation using a read reference voltage level or a read reference voltage level set determined based on: 1) the remaining entries in the HD self-learning table HDSFT that are not included in the prioritized subset during step S107 (e.g., the last 4 entries); and 2) the remaining entries in the default read retry table DRT, excluding those that are already recorded in the HD self-learning table HDSFT.

At step S114, the memory controller 110 determines whether the read retry operation performed at S113 is successful by performing hard-decision ECC decoding. If the read retry operation is successful, the flow proceeds to step S109, where information of the determined read reference voltage level or read reference voltage level set is stored in the HD self-learning table HDSFT (as the highest-priority entry, shifting existing entries downward) corresponding to plane to which the logic address of the normal read command is mapped. In addition, the determined read reference voltage level or read reference voltage level set is further used to update the sticky table ST, ensuring that following normal read operations can leverage this optimized read reference voltage setting.

If the read retry operations based on all remaining entries in the HD self-learning table HDSFT and the default read retry table DRT all fail, the flow transitions to step S115, where a second retry flow comprises read retry operations using soft-decision decoding.

At step S115, the memory controller 110 performs a read retry operation using an iteratively adjusted read reference voltage level or an iteratively adjusted read reference voltage level set based on soft-decision decoding. This iterative adjustment process refines the read reference voltage levels dynamically, leveraging soft-decision decoding techniques to improve the likelihood of retrieving the stored data successfully.

At step S116, the memory controller 110 determines whether the read retry operation is successful by using soft-decision ECC decoding. If the soft-decision ECC decoding confirms that the data has been successfully retrieved, information of the currently adjusted read reference voltage level or the currently adjusted read reference voltage level set used in a final iteration of soft-decision decoding is stored into the SD self-learning table SDSFT (as the highest-priority entry, shifting existing entries downward) corresponding to the plane to which the logic address of the normal read command is mapped. Additionally, the sticky table ST is updated on a superblock basis accordingly to reflect the most recent successful read reference voltage level or the most recent successful read reference voltage level set.

If the read retry operation at step S115 is unsuccessful, the flow proceeds to step S118. At step S118, the memory controller 110 transitions into a redundant array of inexpensive disks (RAID)-like decoding flow. Typically, apart from using the ECC at the page level to protect data integrity, a RAID-like parity protection mechanism (e.g., XOR-based parity or Reed-Solomon encoding across multiple blocks or dies) is employed to further enhance data recoverability. The RAID decoding flow attempts to reconstruct the lost or unreadable data by leveraging redundant parity information stored across different memory blocks or dies. If the RAID decoding succeeds, the reconstructed data is returned to the host device 50.

At step S119, if the read retry operation is eventually successful, the memory controller 110 sets a retention flag to mark the affected block (or superblock) to which the logic address of the normal read command is mapped to for reclaim garbage collection (GC) operation. Accordingly, the GC process executed by the memory controller 110 can schedule the flagged block for data moving and erasure, helping maintain overall data reliability and performance.

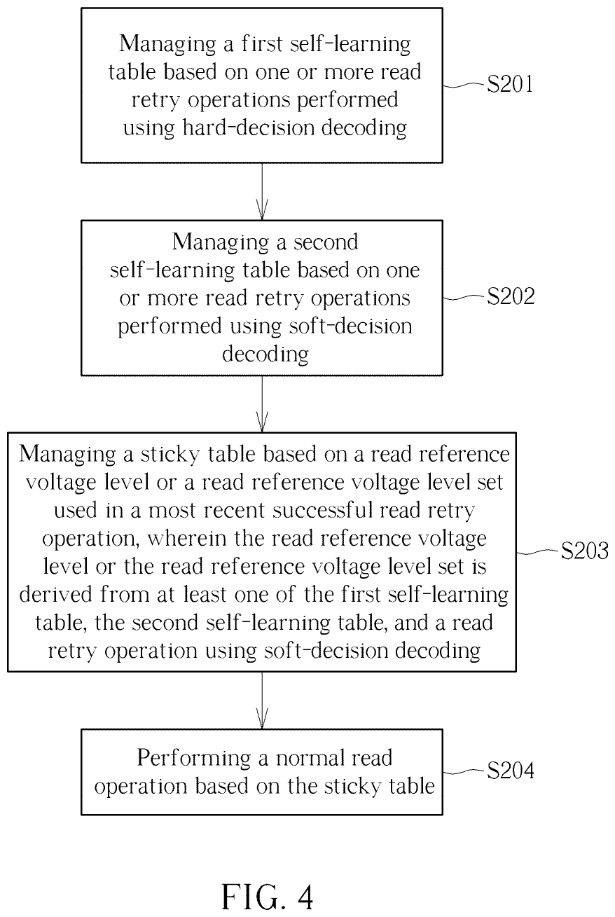

FIG. 4 illustrates a flow chart of a method of performing read reference voltage management on a flash memory according to one embodiment of the present invention. As shown in the figure, the method of performing read reference voltage management includes the following steps:
S201: managing a first self-learning table based on one or more read retry operations performed using hard-decision decoding;
S202: managing a second self-learning table based on one or more read retry operations performed using soft-decision decoding;
S203: managing a sticky table based on a read reference voltage level or a read reference voltage level set used in a most recent successful read retry operation, wherein the read reference voltage level or the read reference voltage level set is derived from at least one of the first self-learning table, the second self-learning table, and a read retry operation using soft-decision decoding; and
S204: performing a normal read operation based on the sticky table.

Since the principle and specific details of the foregoing steps have been described expressly in the above embodiments, further descriptions will not be repeated here. It should be noted that the above flow may achieve better the read performance of the flash memory by adding other extra steps or making appropriate modifications and/or adjustments.

Embodiments in accordance with the present embodiments can be implemented as an apparatus, method, or computer program product. Accordingly, the present embodiments may take the form of an entirely hardware embodiment, an entirely software embodiment, or an embodiment combining software and hardware aspects that can all generally be referred to herein as a “module” or “system.” Furthermore, the present embodiments may take the form of a computer program product embodied in any tangible medium of expression having computer-usable program code embodied in the medium. In terms of hardware, the present invention can be accomplished by applying any of the following technologies or related combinations: an individual operation logic with logic gates capable of performing logic functions according to data signals, and an application specific integrated circuit (ASIC), a programmable gate array (PGA) or a field programmable gate array (FPGA) with a suitable combinational logic.

The flowchart and block diagrams in the flow diagrams illustrate the architecture, functionality, and operation of possible implementations of systems, methods, and computer program products according to various embodiments of the present embodiments. In this regard, each block in the flowchart or block diagrams may represent a module, segment, or portion of code, which comprises one or more executable instructions for implementing the specified logical function(s). It is also noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions. These computer program instructions can be stored in a computer-readable medium that directs a computer or other programmable data processing apparatus to function in a particular manner, such that the instructions stored in the computer-readable medium produce an article of manufacture including instruction means which implement the function/act specified in the flowchart and/or block diagram block or blocks.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for performing read reference voltage management on a flash memory, comprising:
managing a first self-learning table based on one or more read retry operations performed using hard-decision decoding;
managing a second self-learning table based on one or more read retry operations performed using soft-decision decoding;
managing a sticky table based on a read reference voltage level or a read reference voltage level set used in a most recent successful read retry operation, wherein the read reference voltage level or the read reference voltage level set is derived from at least one of the first self-learning table, the second self-learning table, and a read retry operation using soft-decision decoding; and
performing a normal read operation based on the sticky table.

2. The method of claim 1, wherein the step of managing the first self-learning table comprises:
determining a read reference voltage level or a read reference voltage level set based on a default read retry table;
performing at least one read retry operation using the determined read reference voltage level or the determined read reference voltage level set;
determining whether the read retry operation is successful based on hard-decision decoding; and
storing information about the determined read reference voltage level or read reference voltage level set as an entry in the first self-learning table when the read retry operation is successful.

3. The method of claim 2, wherein the step of managing the second self-learning table comprises:
performing at least one read retry operation using an iteratively adjusted read reference voltage level or an iteratively adjusted read reference voltage level set based on soft-decision decoding;
determining whether the read retry operation is successful based on soft-decision decoding; and
storing information about the adjusted read reference voltage level or read reference voltage level set as an entry in the second self-learning table when the read retry operation is successful.

4. The method of claim 3, further comprising:
in response to a failure of the normal read operation, performing a first retry flow including one or more read retry operation using hard-decision decoding, comprising:
performing a first read retry operation using a read reference voltage level or a read reference voltage level set determined based on one of a prioritized subset of entries in the first self-learning table; and
if the first read retry operation is successful, storing information about the determined read reference voltage level or the determined read reference voltage level set as a highest-priority entry in the prioritized subset of entries in the first self-learning table and updating the sticky table accordingly.

5. The method of claim 4, wherein the first retry flow comprises:
if the first read retry operation based on all entries of the prioritized subset of entries in the first self-learning table is unsuccessful, performing a second read retry operation using a read reference voltage level or a read reference voltage level set determined based on one of entries in the second self-learning table; and
if the second read retry operation is successful, storing information about the determined read reference voltage level or the determined read reference voltage level set as a highest-priority entry in the second self-learning table and updating the sticky table accordingly.

6. The method of claim 5, wherein the first retry flow further comprises:
if the second read retry operation based on all entries in the second self-learning table is unsuccessful, performing a third read retry operation using a read reference voltage level or a read reference voltage level set determined based on one of the remaining entries in the default read retry table, excluding those already recorded in the prioritized subset of entries in the first self-learning table; and
if the third read retry operation is successful, storing information about the determined read reference voltage level or the determined read reference voltage level set as a highest-priority entry in the first self-learning table and updating the sticky table accordingly.

7. The method of claim 6, further comprising:
if the third read retry operation based on all the remaining entries in the default read retry table is unsuccessful, performing a second retry flow including one or more read retry operation using soft-decision decoding, comprising:
performing a fourth read retry operation using an iteratively adjusted read reference voltage level or an iteratively adjusted read reference voltage level set based on soft-decision decoding; and
if the fourth read retry operation is successful, storing the information about the currently adjusted read reference voltage level or the currently adjusted read reference voltage level set used in a final iteration of the soft-decision decoding as a highest-priority entry in the second self-learning table and updating the sticky table accordingly.

8. The method of claim 1, wherein the first self-learning table and the second self-learning table are managed per plane, and a plane is a subdivision of a memory die or chip of the flash memory, which includes a plurality of memory blocks and is independently accessible.

9. The method of claim 1, wherein the sticky table is managed per superblock, and a superblock is a collection of memory blocks that are logically grouped together across a plurality of memory dies or chips included in the flash memory.

10. The method of claim 1, further comprising:
performing a normal read operation using a default read reference voltage level when the sticky table is unavailable.

11. A memory controller for use in a flash memory, comprising:
a storage unit configured to store program codes;
a processing unit configured to execute the program code to perform operations on the flash memory, comprising:
managing a first self-learning table based on one or more read retry operations performed using hard-decision decoding;
managing a second self-learning table based on one or more read retry operations performed using soft-decision decoding;
managing a sticky table based on a read reference voltage level or a read reference voltage level set used in a most recent successful read retry operation, wherein the read reference voltage level or the read reference voltage level set is derived from at least one of the first self-learning table, the second self-learning table, and a read retry operation using soft-decision decoding; and
performing a normal read operation based on the sticky table.

12. The memory controller of claim 11, wherein when the program codes is executed by the processing unit, the memory controller is configured to:
determining a read reference voltage level or a read reference voltage level set based on a default read retry table;
performing at least one read retry operation using the determined read reference voltage level or the determined read reference voltage level set;
determine whether the read retry operation is successful based on hard-decision decoding; and
store information about the determined read reference voltage level or the determined read reference voltage level set as an entry in the first self-learning table when the read retry operation is successful.

13. The memory controller of claim 12, wherein when the program codes is executed by the processing unit, the memory controller is configured to:
perform at least one read retry operation using an iteratively adjusted read reference voltage level or an iteratively adjusted read reference voltage level set based on soft-decision decoding;
determine whether the read retry operation is successful based on soft-decision decoding; and
store information about the adjusted read reference voltage or read reference voltage level set as an entry in the second self-learning table when the read retry operation is successful.

14. The memory controller of claim 13, wherein when the program codes is executed by the processing unit, the memory controller is configured to:
in response to a failure of the normal read operation, performing a first retry flow including one or more read retry operation using hard-decision decoding, comprising;
perform a first read retry operation using a read reference voltage level or a read reference voltage level set determined based on one of a prioritized subset of entries in the first self-learning table; and
if the first read retry operation is successful, store information about the determined read reference voltage level or the determined read reference voltage level set as a highest-priority entry in the prioritized subset of entries in the first self-learning table and update the sticky table accordingly.

15. The memory controller of claim 14, wherein when the program codes is executed by the processing unit, the memory controller is configured to:
if the first read retry operation based on all entries of the prioritized subset of entries in the first self-learning table is unsuccessful, perform a second read retry operation using a read reference voltage level or a read reference voltage level set determined based on one of entries in the second self-learning table; and
if the second read retry operation is successful, store information about the determined read reference voltage level or the determined read reference voltage level set as a highest-priority entry in the second self-learning table and update the sticky table accordingly.

16. The memory controller of claim 15, wherein when the program codes is executed by the processing unit, the memory controller is configured to:
if the second read retry operation based on all entries in the second self-learning table is unsuccessful, perform a third read retry operation using a read reference voltage level or a read reference voltage level set determined based on one of the remaining entries in the default read retry table, excluding those already recorded in the prioritized subset of entries in the first self-learning table; and
if the third read retry operation is successful, store information about the determined read reference voltage level or the determined read reference voltage level set as a highest-priority entry in the first self-learning table and updating the sticky table accordingly.

17. The memory controller of claim 16, wherein when the program codes is executed by the processing unit, the memory controller is configured to:
if the third read retry operation based on all the remaining entries in the default read retry table is unsuccessful, perform a second retry flow including one or more read retry operation using soft-decision decoding;
perform a fourth read retry operation using an iteratively adjusted read reference voltage level or an iteratively adjusted read reference voltage level set based on soft-decision decoding; and
if the fourth read retry operation is successful, store the information about the currently adjusted read reference voltage level or the currently adjusted read reference voltage level set used as a highest-priority entry in the second self-learning table and updating the sticky table accordingly.

18. The memory controller of claim 11, wherein the first self-learning table and the second self-learning table are managed per plane, and a plane is a subdivision of a memory die or chip of the flash memory, which includes a plurality of memory blocks and is independently accessible.

19. The memory controller of claim 11, wherein the sticky table is managed per superblock, and a superblock is a collection of memory blocks that are logically grouped together across a plurality of memory dies or chips included in the flash memory.

20. The memory controller of claim 11, wherein when the program codes is executed by the processing unit, the memory controller is configured to:
performing a normal read operation using a default read reference voltage level when the sticky table is unavailable.

21. A data storage device comprising a memory controller of claim 11 and a flash memory.
